(19) United States
(12) Patent Application Publication
(10) Pub. No.: US 2025/0066641 A1
(43) Pub. Date: Feb. 27, 2025

(54) POLISHING SLURRY COMPOSITION AND METHOD OF MANUFACTURING INTEGRATED CIRCUIT DEVICE USING THE SAME

(71) Applicant: Samsung Electronics Co., Ltd., Suwon-si (KR)

(72) Inventor: Sanghwa LEE, Suwon-si (KR)

(73) Assignee: Samsung Electronics Co., Ltd., Suwon-si (KR)

(21) Appl. No.: 18/602,177

(22) Filed: Mar. 12, 2024

(30) Foreign Application Priority Data
Jul. 20, 2023 (KR) 10-2023-0094654

(51) Int. Cl. C09G 1/04

(52) U.S. Cl. CPC C09G 1/04

(57) ABSTRACT

A polishing slurry composition may include water and an abrasive including a cerium-based metal organic framework. The cerium-based metal organic framework may have a three-dimensional (3D) network structure including a plurality of cerium hexanuclear nanoclusters and a plurality of organic linkers. Each of the plurality of cerium hexanuclear nanoclusters may include six cerium atoms and each of the plurality of organic linkers may be connected between two corresponding cerium hexanuclear nanoclusters among the plurality of cerium hexanuclear nanoclusters. A method of manufacturing an integrated circuit (IC) device may include forming a film to be polished on a substrate, and polishing the film to be polished by performing a chemical mechanical polishing (CMP) process using the polishing slurry composition.

### CROSS-REFERENCE TO RELATED APPLICATION

This application is based on and claims priority under 35 U.S.C. § 119 to Korean Patent Application No. 10-2023-0094654, filed on Jul. 20, 2023, in the Korean Intellectual Property Office, the disclosure of which is incorporated by reference herein in its entirety.

### BACKGROUND

Inventive concepts relate to a slurry composition and/or a method of manufacturing integrated circuit (IC) device using the same, and more particularly, to a slurry composition for polishing a film to be polished, by using a chemical mechanical polishing (CMP) process, and/or a method of manufacturing an IC device using the polishing slurry composition.

Due to the development of electronics technology, the downscaling of semiconductor devices has rapidly progressed. Accordingly, the linewidth and pitch of unit devices included in IC devices have also been miniaturized. Therefore, there may be a need to improve the lifespan and reliability of IC devices by increasing polishing efficiency of a film to be polished and minimizing physical damage to the film to be polished.

### SUMMARY

Inventive concepts provide a polishing slurry composition, which may increase a polishing rate of a film to be polished while limiting and/or preventing defects (e.g., scratches) on a polished surface of the film to be polished or physical damage to the polished surface of the film to be polished during the polishing of the film to be polished.

Inventive concepts also provide a method of manufacturing an integrated circuit (IC) device, which may improve IC manufacturing productivity and improve the reliability of IC devices by increasing a polishing rate of a film to be polished while limiting and/or preventing the occurrence of defects (e.g., scratches) or physical damage on a polished surface of the film to be polished.

According to an embodiment of inventive concepts, a polishing slurry composition may include an abrasive and water. The abrasive may include a cerium-based metal organic framework. The cerium-based metal organic framework may have a three-dimensional (3D) network structure including a plurality of cerium hexanuclear nanoclusters and a plurality of organic linkers. Each of the plurality of cerium hexanuclear nanoclusters may include six cerium atoms, and each of the plurality of organic linkers may be connected between two corresponding cerium hexanuclear nanoclusters among the plurality of cerium hexanuclear nanoclusters.

According to an embodiment of inventive concepts, a polishing slurry composition may include an abrasive and water. The abrasive may include a cerium-based metal organic framework having a three-dimensional (3D) network structure. The cerium-based metal organic framework may include a bonding structure represented by General formula 1,

{[Ce₆]-L}ₙ [General formula 1]

In General formula 1, [Ce₆] may be a cerium hexanuclear nanocluster including six cerium atoms and a plurality of oxygen atoms, L may be an organic linker, and n may be an integer of 2 or more.

According to an embodiment of inventive concepts, a method of manufacturing an IC device may include forming a film to be polished on a substrate; and polishing the film to be polished by performing a chemical mechanical polishing (CMP) process using a slurry composition. The slurry composition may include an abrasive and water. The abrasive may include a cerium-based metal organic framework. The cerium-based metal organic framework may have a three-dimensional (3D) network structure including a plurality of cerium hexanuclear nanoclusters. Each of the plurality of cerium hexanuclear nanoclusters may include six cerium atoms and a plurality of organic linkers. Each of the plurality of organic linkers may be connected between two corresponding cerium hexanuclear nanoclusters among the plurality of cerium hexanuclear nanoclusters.

### BRIEF DESCRIPTION OF THE DRAWINGS

Embodiments of inventive concepts will be more clearly understood from the following detailed description taken in conjunction with the accompanying drawings in which:

FIG. 1 is a partially cut-away perspective view of some components of a polishing apparatus according to embodiments;

FIG. 2 is a conceptual perspective view of an example of a cerium-based metal organic framework that may be included in a slurry composition according to embodiments;

FIG. 3A is a conceptual perspective view of a schematic crystal structure of the cerium hexanuclear nanocluster shown in FIG. 2;

FIG. 3B illustrates a chemical structure of an organic linker shown in FIG. 1;

FIG. 4 is a flowchart of a method of manufacturing an integrated circuit (IC) device, according to embodiments; and

FIGS. 5A and 5B are cross-sectional views of a process sequence of a method of manufacturing an IC device, according to embodiments.

### DETAILED DESCRIPTION

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

Hereinafter, embodiments will be described in detail with reference to the accompanying drawings. The same reference numerals are used to denote the same elements in the drawings, and repeated descriptions thereof will be omitted.

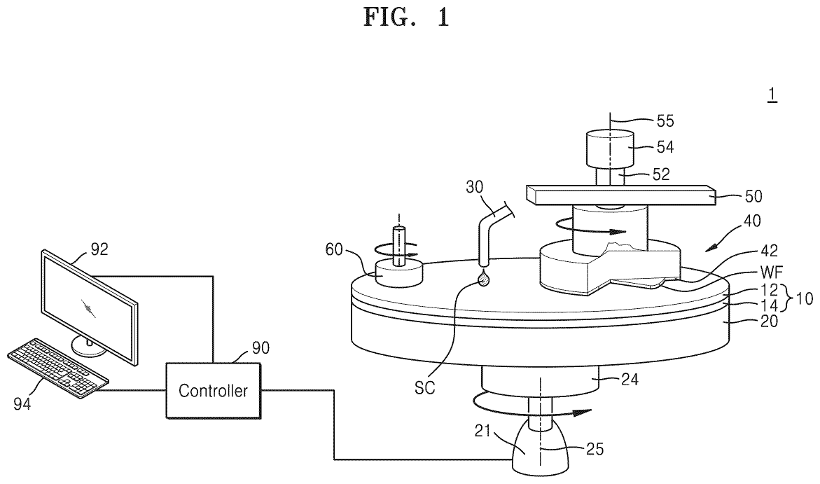

FIG. 1 is a partially cut-away perspective view of some components of a polishing apparatus according to embodiments.

Referring to FIG. 1, a polishing apparatus 1 may be used to polish a surface of a wafer WF by using a chemical mechanical polishing (CMP) process. A rotary polishing apparatus is illustrated as an example of the polishing apparatus 1 in FIG. 1.

The polishing apparatus 1 may include a platen 20 having a rotating disc shape. The platen 20 may be capable of rotating about a central axis 25 thereof by using a motor 21. For example, the motor 21 may turn a driving axis 24 to rotate the platen 20. A polishing pad 10 is placed on a top surface of the platen 20. The polishing pad 10 may include a polishing layer 12 and a support layer 14. The support layer 14 may support the polishing pad 10 to be adhered to the platen 20.

A film to be polished may be exposed on the wafer WF and may be an insulating film, a semiconductor film, a metal film, or an alloy film, but is not limited thereto. The wafer WF may include a structure configured to form an integrated circuit (IC) device, a structure configured to form a thin film transistor-liquid crystal display (TFT-LCD), and/or a structure including various substrates, such as a glass substrate, a ceramic substrate, and a polymer substrate.

The polishing apparatus 1 may include a slurry port 30 configured to dispense a metal-polishing slurry composition SC according to embodiments onto the polishing pad 10. The polishing apparatus 1 may include a polishing pad conditioner 60. The polishing pad conditioner 60 may perform a dressing operation of periodically polishing and planarizing a surface of the polishing pad 10 so that the polishing pad 10 may provide constant polishing efficiency. As used herein, the term “slurry composition” refers to a polishing slurry composition that may be used to polish a film to be polished, in a CMP process. As used herein, the slurry composition may be synonymous with the polishing slurry composition.

The polishing apparatus 1 may include at least one carrier head 40. The wafer WF may be loaded on the carrier head 40. In a state in which the wafer WF loaded on the carrier head 40 is positioned to face the platen 20, the carrier head 40 may rotate while rotating the wafer WF toward the platen 20. Although only one carrier head 40 is illustrated on the polishing pad 10 in FIG. 1, a plurality of carrier heads 40 may be on the polishing pad 10. The carrier head 40 may control pressure applied to the wafer WF.

The carrier head 40 may include a retaining ring 42 for holding the wafer WF. The carrier head 40 may be supported by a support structure 50 (e.g., a carousel or a track) and be connected to a carrier head rotational motor 54 by a driving axis 52, and thus, the carrier head 40 may rotate about a central axis 55 of the driving axis 52.

The polishing apparatus 1 may further include a control system configured to control rotation of the platen 20. The control system may include a controller 90 (e.g., a general-use programmable digital computer), an output device 92 (e.g., a monitor), and an input device 94 (e.g., a keyboard). Although FIG. 1 illustrates an example in which the control system is connected only to the motor 21, inventive concepts are not limited thereto. The control system may be also connected to the carrier head 40 and control the pressure or rotation speed of the carrier head 40. Furthermore, the control system may be connected to the slurry port 30 and control the supplying of the metal-polishing slurry composition SC.

The slurry composition SC according to embodiments may be used to polish a film to be polished on the wafer WF. The slurry composition SC may include an abrasive including a cerium (Ce)-based metal organic framework, and water. The cerium-based metal organic framework may have a 3D network structure including a plurality of cerium hexanuclear nanoclusters, each of which includes six cerium atoms, and a plurality of organic linkers, each of which is connected between two selected ones of the plurality of cerium hexanuclear nanoclusters. As used herein, the term “metal organic framework” refers to a structure in which metal ions and organic materials, each of which is chemically bonded between two adjacent ones of the metal ions, form a lattice (frame). The chemical bond may be a coordinate bond, a covalent bond, or chemisorption.

The cerium-based metal organic framework may have various 3D structures, various sizes, various volumes, and various chemical properties according to types of the plurality of organic linkers included in the cerium-based metal organic framework. The cerium-based metal organic framework may be coordinately bonded to the plurality of organic linkers with strong bonding force between the plurality of cerium hexanuclear nanoclusters and oxygen atoms provided by the plurality of organic linkers. Accordingly, as compared to a typical metal organic framework including a divalent metal or a trivalent metal, the cerium-based metal organic framework may have relatively high mechanical stability and chemical stability.

In embodiments, the cerium-based metal organic framework may include a bonding structure represented by General formula 1:

{[Ce₆]-L}ₙ [General formula 1]

wherein [Ce₆] is a cerium hexanuclear nanocluster including six cerium atoms and a plurality of oxygen atoms, L is an organic linker, and n is an integer of 2 or more.

In embodiments, in General formula 1, n may be an integer selected in a range of about 2 to about 300 or a range of about 2 to about 600, without being limited thereto.

In embodiments, the cerium hexanuclear nanocluster may have a composition represented by Formula 1:

[Ce₆Oₓ(OH)₈₋ₓ(NH₃CH₂COO)₈]A_{y} [Formula 1]

wherein x is an integer of 4 to 8, y is an integer of 1 to 8, and A includes at least one of carboxylate, nitrate, amino acid salt, and a chlorine ion.

In other embodiments, the cerium hexanuclear nanocluster may have a composition represented by Formula 2:

[Ce₆O₄(OH)₄(NH₃CH₂COO)₈(NO₃)₄(H₂O)₆Cl₈·8H₂O] [Formula 2]

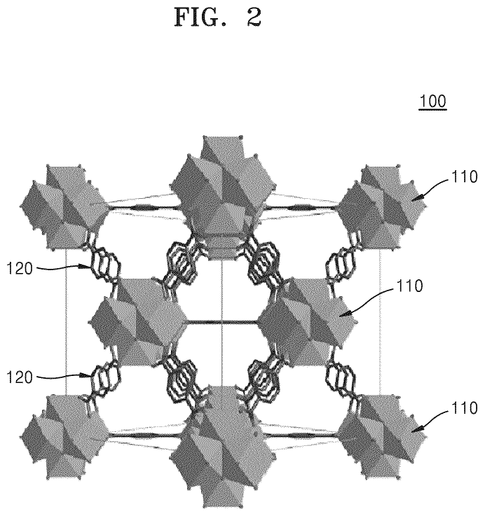

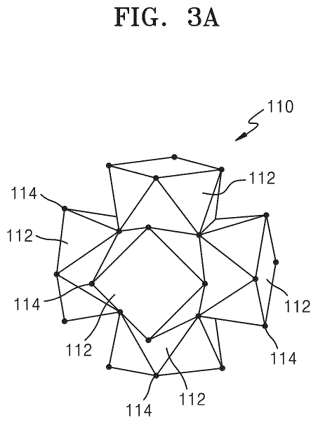

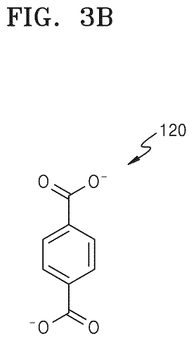

FIG. 2 is a conceptual perspective view of an example of a cerium-based metal organic framework 100 that may be included in a slurry composition SC according to embodiments. FIG. 3A is a conceptual perspective view of a schematic crystal structure of a cerium hexanuclear nanocluster 110 shown in FIG. 2. FIG. 3B illustrates a chemical structure of an organic linker 120 shown in FIG. 1.

Referring to FIGS. 2, 3A, and 3B, the cerium-based metal organic framework 100 may include a plurality of cerium hexanuclear nanoclusters 110 and a plurality of organic linkers 120, each of which is connected between two selected ones of the plurality of cerium hexanuclear nanoclusters 110. Each of the plurality of cerium hexanuclear nanoclusters 110 may include six cerium atoms 112 and a plurality of oxygen atoms 114.

In embodiments, each of the plurality of cerium hexanuclear nanoclusters 110 included in the cerium-based metal organic framework 100 may have a polyoxometalate structure in which six CeOₓ (x is 8 or 9) polyhedrons, each of which includes {CeO₈}, {CeO₉}, or a combination thereof, are connected to each other through an oxo bridge and/or a hydroxo bridge. Each of the plurality of cerium hexanuclear nanoclusters 110 may have a polyanionic 3D frame structure having a polyhedral crystal structure. In embodiments, each of the plurality of cerium hexanuclear nanoclusters 110 may have an average particle size of about 1 nm to about 2 nm, without being limited thereto.

Although FIGS. 2 and 3B illustrate an example in which the organic linker 120 is benzene-1,4-dicarboxylic acid (also referred to as terephthalate), inventive concepts are not limited thereto.

In embodiments, each of the plurality of organic linkers 120 that constitute the cerium-based metal organic framework 100 may have a plurality of anionic functional groups and be chemically bonded to at least two selected ones of the plurality of cerium hexanuclear nanoclusters 110 through the plurality of anionic functional groups. The chemical bond may be a coordinate bond, a covalent bond, or chemisorption. For example, the chemical bond may be the coordinate bond, without being limited thereto.

In embodiments, each of the plurality of organic linkers 120 that constitute the cerium-based metal organic framework 100 may be a charged organic linker. The charged organic linker may include a carboxylate functional group (—COO⁻) and an anionic functional group (e.g., sulfate (SO₃⁻)). Each of the plurality of organic linkers 120 may include at least two charged functional groups. In embodiments, each of the plurality of organic linkers 120 may include a bidentate ligand, a tridentate ligand, or a tetradentate ligand. For example, each of the plurality of organic linkers 120 may have two, three, or four carboxylate functional groups (—COO⁻).

In the slurry composition SC according to embodiments, each of a plurality of organic linkers that may be included in the cerium-based metal organic framework that constitutes an abrasive may include substituted or unsubstituted C1 to C20 alkyl, substituted or unsubstituted C2 to C20 alkenyl, substituted or unsubstituted C2 to C20 alkynyl, substituted or unsubstituted C1 to C20 heteroalkyl, substituted or unsubstituted C2 to C20 heteroalkenyl, substituted or unsubstituted C2 to C20 heteroalkynyl, substituted or unsubstituted C3 to C20 cycloalkyl, substituted or unsubstituted C3 to C20 cycloalkenyl, or a substituted or unsubstituted C6 to C30 aromatic ring system. For example, each of the plurality of organic linkers included in the cerium-based metal organic framework may include an aromatic ring.

When at least some of the plurality of organic linkers have a substituted hydrocarbon group, some or all of hydrogen atoms included in the hydrocarbon group included in the organic linker may be replaced by a substituent. As used herein, the term “substituent” refers to an atom or a group of atoms, which is substituted for a hydrogen atom in a structure. The substituent may be selected from a halogen atom, a hydroxyl group, a sulfonic group, a carboxyl group, an amino group, a nitro group, a cyano group, and a thiol (—SH) group, without being limited thereto.

In embodiments, each of the plurality of organic linkers included in the cerium-based metal organic framework that constitutes the slurry composition SC may include carboxylate obtained from an organic compound. For example, each of the plurality of organic linkers may include carboxylate obtained from at least one organic compound selected from the group of benzene-1,4-dicarboxylic acid, 5-bromoisophthalic acid, 2-hydroxyterephthalic acid, 2,5-dihydroxyterephthalic acid, 5-cyano-1,3-benzenedicarboxylic acid, 2,5-diaminoterephthalic acid, 5-ethynyl-1,3-benzenedicarboxylic acid, 4,4′-biphenyldicarboxilic acid, 2,6-naphthalenedicarboxylic acid, 9,10-anthracenedicarboxylic acid, 2,2-diamino-4,4′-stilbenedicarboxylic acid, 2,2-dinitro-4,4-stilbenedicarboxylic acid, 1,3,5-tricarboxybenzene, biphenyl-3,4′,5-tricarboxylic acid, 1,3,5-tris(4-carboxyphenyl)benzene, 2,4,6-Tris(4-carboxyphenyl)-1,3,5-triazine, 1,3,5-tris(4-carboxy[1,1′-biphenyl]-4-yl)benzene, biphenyl-3,3,5,5′-tetracarboxylic acid, 1,2,4,5-tetrakis(4-carboxyphenyl)benzene, 1,4,7,10-tetraazacyclododecane-N,N′,N″,N′″-tetraacetic acid, and 1,1,2,2-tetra(4-carboxylphenyl)ethylene, without being limited thereto.

In embodiments, the plurality of organic linkers included in the cerium-based metal organic framework that constitutes the slurry composition SC may include carboxylate obtained from at least one organic compound selected from the following structures:

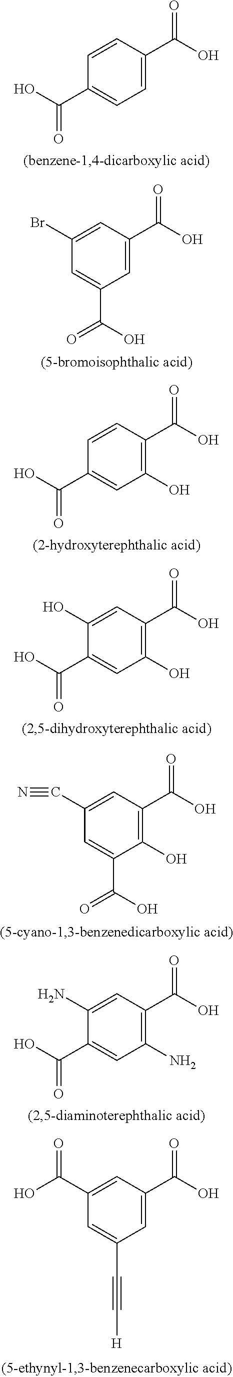

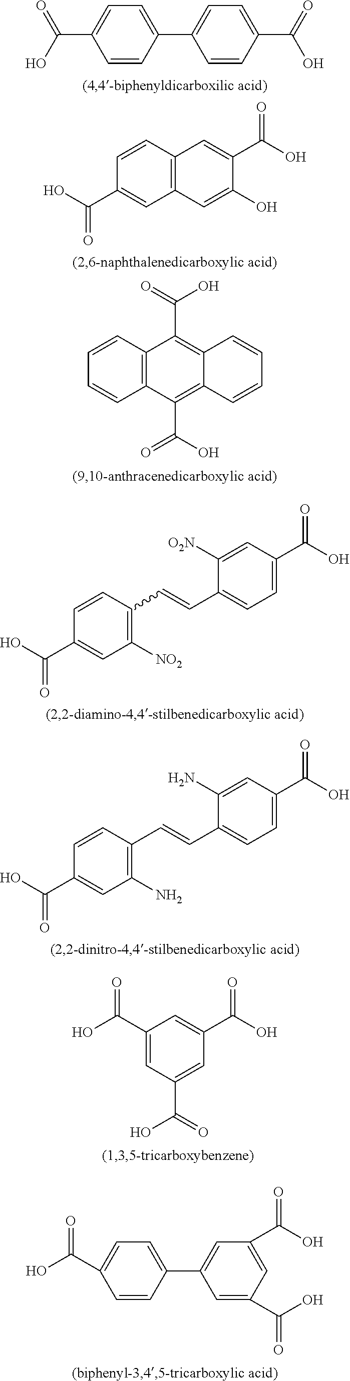

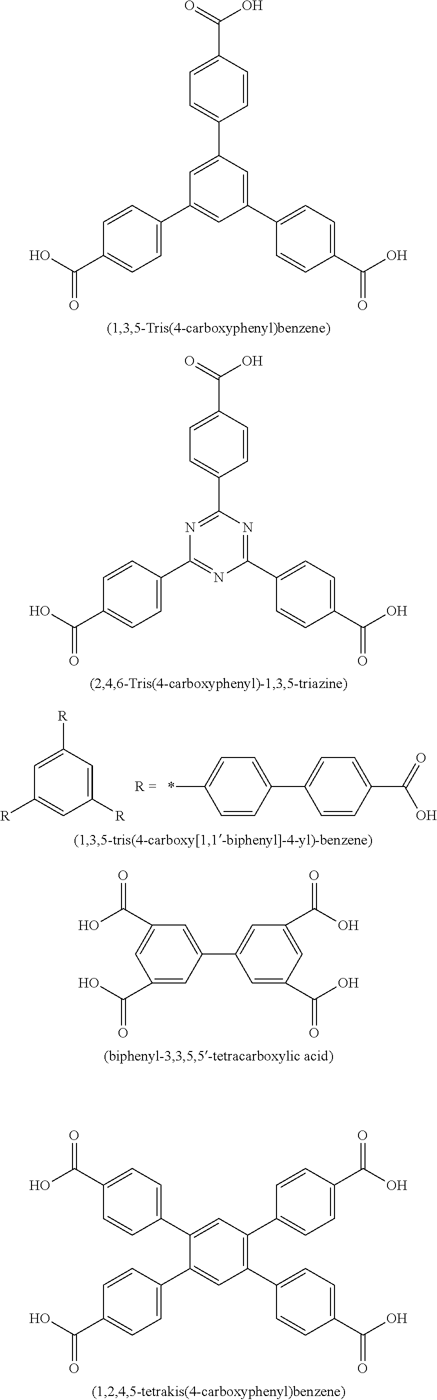

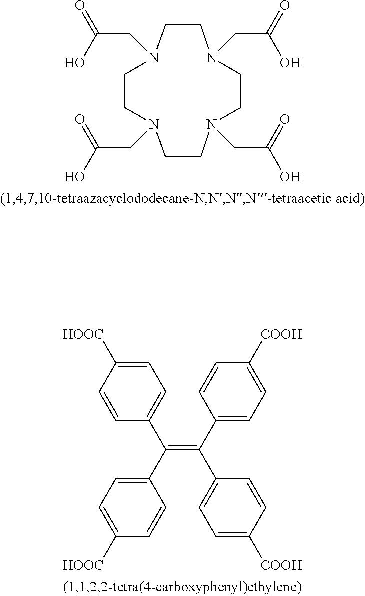 [SMILES: O=C(O)CN1CCN(CC(=O)O)CCN(CC(=O)O)CCN(CC(=O)O)CC1 ; O=C(O)c1ccc(C(=C(c2ccc(C(=O)O)cc2)c2ccc(C(=O)O)cc2)c2ccc(C(=O)O)cc2)cc1]

For example, from among the organic compounds, each of benzene-1,4-dicarboxylic acid, 2,6-naphthalenedicarboxylic acid, and 1,3,5-tris(4-carboxyphenyl)benzene may be in the following forms of carboxylates in the cerium-based metal organic framework:

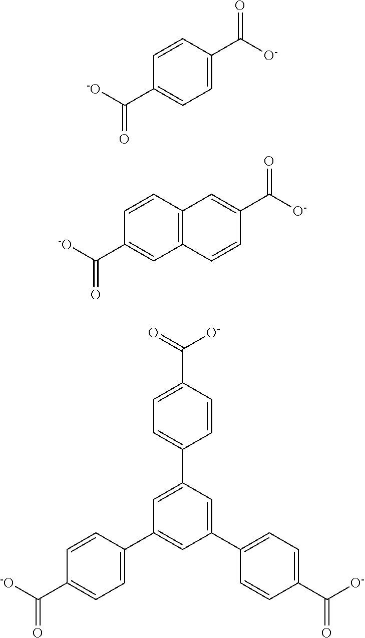

In embodiments, a size of the cerium-based metal organic framework included in the slurry composition SC may be in a range of about 0.1 m to about 100 m, without being limited thereto.

The slurry composition SC according to embodiments may further include a dispersant. The dispersant may improve the dispersion of the cerium-based metal organic framework used as an abrasive in the slurry composition SC. Because the dispersant is included in the slurry composition SC, a polishing rate may be limited and/or prevented from decreasing in a polishing process using the slurry composition SC, and the polishing uniformity of a film to be polished may be increased by improving dispersibility of the cerium-based metal organic framework included in the slurry composition SC.

In embodiments, the dispersant may include at least one material selected from polyethylene glycol, polypropylene glycol, polyvinyl alcohol, polyvinyl pyrrolidone, polyoxy alkylene alkylether, polyoxy alkylene alkylester, polyoxy propylene ether, polyoxy ethylene methylether, polyethylene glycol sulphonic acid, polyethylene oxide, polypropylene oxide, polyalkyl oxide, polyoxy ethylene oxide, polyethylene oxide-propylene oxide copolymer, cellulose, methylcellulose, methylhydroxy ethylcellulose, methylhydroxy propylcellulose, hydroxy ethylcellulose, carboxy methylcellulose, carboxy methylhydroxy ethylcellulose, glycerin, polypropylene glycol, sulfoethyl cellulose, and carboxy methyl sulfoethyl cellulose.

In embodiments, the dispersant may be included at a content of about 0.01 wt % to about 15 wt %, for example, a content of about 0.05 wt % to about 10 wt % or a content of about 1 wt % to about 5 wt %, based on a total weight of the slurry composition SC, without being limited thereto.

The slurry composition SC according to embodiments may further include a pH adjuster. The pH adjuster may adjust a pH value of the slurry composition SC to a desired value.

In embodiments, the pH adjuster may include potassium hydroxide, acetic acid, nitric acid, hydrogen chloride, ammonium hydroxide, sodium hydroxide, tetramethylammonium hydroxide, or a combination thereof, without being limited thereto.

In embodiments, the slurry composition SC may have a pH value selected within a range of about 2 to about 11. For example, the slurry composition SC may have a pH value of about 4 to about 10 or a pH value of about 5 to about 8. To adjust a pH value of the slurry composition SC to a desired value, a pH adjuster including an acidic solution and/or an alkali solution may be used in an appropriate amount. In the slurry composition SC, the pH adjuster may be included in an amount necessary to adjust a polishing slurry composition to a desired pH value, but a content of the pH adjuster is not specifically limited.

The slurry composition SC according to embodiments may further include a corrosion inhibitor. The corrosion inhibitor may be selectively adhered to the film to be polished, and may effectively inhibit excessive corrosion of the film to be polished while maintaining a good polishing rate of the film to be polished.

The corrosion inhibitor may include a water-soluble including an azole-containing compound or an anionic carboxylic acid. In embodiments, the corrosion inhibitor may include an azole-containing compound, and the azole-containing compound may include triazole, tetrazole, benzotriazole, tolytriazole, aminotriazole, aminobenzimidazole, pyrazole, imidazole, inotetrazole, or a combination thereof. For example, the corrosion inhibitor may include 5-methyl-1H-benzotriazol, 2,2′-[[(5-methyl-H-benzotriazole-1-yl)-methyl]imino]bis-ethanol, 1,2,4-triazole, 1,2,3-triazole, 1,2,3-triazolo[4,5-b]pyridine, or a combination thereof.

When the corrosion inhibitor is included in the slurry composition SC, a content of the corrosion inhibitor may be in a range of about 0.001 wt % to about 1 wt %, for example, a range of about 0.001 wt % to about 0.5 wt %, based on a total weight of the slurry composition SC without being limited thereto.

The slurry composition SC according to embodiments may further include a polishing booster. The polishing booster may increase a polishing rate of the film to be polished.

In embodiments, the polishing booster may include a cationic polymer salt including a quaternary ammonium cation, or an organic acid. In other embodiments, the polishing booster may include arginine, histidine, lysine, aspartic acid, glutamic acid, serine, threonine, asparagine, glutamine, cysteine, selenocysteine, glycine, proline, alanine, valine, leucine, isoleucine, methionine, phenylalanine, tyrosine, tryptophan, carboxylic acid, or a combination thereof.

When the polishing booster includes a polymer, the polishing booster may have a molecular weight of about 1,000 to about 1,000,000. The molecular weight may be a weight-averaged molecular weight. When the polishing booster has an excessively low molecular weight, the polishing rate may be reduced. When the polishing booster has an excessively high molecular weight, dispersibility may be lowered and thus, uniform polishing may be difficult.

When the polishing booster is included in the slurry composition SC, a content of the polishing booster may be in a range of about 0.001 wt % to about 10 wt %, based on a total weight of the slurry composition SC, without being limited thereto.

The slurry composition SC according to embodiments may further include an organic acid to suppress a polishing rate of an inorganic film. The organic acid may contribute to controlling a polishing rate, dispersion stability of the slurry composition SC, and surface characteristics of a film to be polished, in the polishing process using the slurry composition SC. The organic acid may include malic acid, citric acid, formic acid, glutaric acid, oxalic acid, phthalic acid, succinic acid, tartaric acid, maleic acid, malonic acid, or a combination thereof.

When the organic acid is included in the slurry composition SC, a content of the organic acid may be in a range of about 0.02 wt % to about 0.1 wt % or a range of about 0.05 wt % to 0.1 wt %, based on a total weight of the slurry composition SC, without being limited thereto.

The slurry composition SC according to embodiments may further include a biocide. The biocide may limit and/or prevent the slurry composition SC or an object to be polished to which the slurry composition SC is applied, from being contaminated with microorganisms.

In embodiments, the biocide may include an organo tin compound, salicylanilide, formaldehyde, a quaternary ammonium compound, 2-bromo-2-nitropropane-1,3-diol (bronopol), 2,2-dibromo-3-nitrilopropionamide (DBNPA), isothiazolone, carbamate, quaternary phosphonium salt (e.g., tetrakis(hydroxymethyl)-phosphonium sulfate (THPS)), sodium chloride, sodium hypochlorite, trichloroisocyanuric acid, dichloroisocyanuric acid, calcium hypochlorite, lithium hypochlorite, chlorine dioxide, ozone, hydrogen peroxide, or a combination thereof, without being limited thereto.

When the biocide is included in the slurry composition SC, a content of the biocide may be in a range of about 0.001 wt % to about 10 wt %, based on a total weight of the slurry composition SC. In embodiments, the content of the biocide may be in a range of about 0.001 wt % to about 5 wt %, a range of about 0.001 wt % to about 3 wt %, or a range of about 0.001 wt % to about 1 wt %, based on a total weight of the slurry composition SC.

In the slurry composition SC, a content of the abrasive including the cerium-based metal organic framework may be in a range of about 0.1 wt % to about 2 wt %, based on a total weight of the slurry composition SC, without being limited thereto.

Water included in the slurry composition SC according to embodiments may be deionized water. A content of water included in the slurry composition SC is not specifically limited and may be included at a content of the remaining percentage together with main components in the slurry composition SC.

In embodiments, various material films may be polished by using the slurry composition SC according to embodiments. For example, a silicon-containing film, such as a silicon oxide film and a silicon film, may be polished by using the slurry composition SC.

The slurry composition SC according to embodiments may include an abrasive including a cerium-based metal organic framework as an abrasive and water. The cerium-based metal organic framework may have a 3D network structure including a plurality of cerium hexanuclear nanoclusters, each of which includes six cerium atoms, and a plurality of organic linkers, each of which is connected between two selected ones of the plurality of cerium hexanuclear nanoclusters.

In general, when a film to be polished is polished by using a typical slurry composition including an inorganic abrasive, it is likely that the inorganic abrasive may damage a polished surface of the film to be polished, depending on polishing conditions. For example, when the film to be polished is polished by using the typical slurry composition including the inorganic abrasive, the inorganic abrasive may damage or contaminate a surface of a polished product of the film to be polished. Also, the inorganic abrasive may shorten a lifespan of a polishing pad (e.g., the polishing pad 10 shown in FIG. 1) used during a polishing process, thereby increasing polishing cost.

As sizes of IC devices, such as memory devices and non-memory devices, decrease, reducing scratch defects during a CMP process may become more important in a process of manufacturing the IC device. To reduce the scratch defects, various attempts have been made to use a relatively soft polishing pad or an abrasive with a relatively small size. However, with typical abrasives having a relatively small size, it may be difficult to apply sufficient physical force to a surface of a film to be polished.

The slurry composition SC according to embodiments may improve the above-described disadvantages of typical abrasives. The slurry composition SC according to embodiments may include the abrasive including the cerium-based metal organic framework, and thus, a polishing rate of the film to be polished may be increased while limiting and/or preventing physical damage or defects (e.g., scratches) on a polished surface of the film to be polished.

More specifically, in the slurry composition SC according to embodiments, a plurality of cerium hexanuclear nanoclusters included in the abrasive including the cerium-based metal organic framework may have relatively soft physical properties and a structure in which six cerium atoms are three-dimensionally combined and not easily decomposed. Also, the cerium hexanuclear nanocluster, which is electrically charged, may be chemically bonded to the plurality of organic linkers and form the 3D network structure with the plurality of organic linkers due to relatively strong bonding force. Accordingly, while the CMP process is being performed by using the slurry composition including the abrasive having the cerium-based metal organic framework, there is no fear of the cerium hexanuclear nanoclusters falling off from the abrasive. In addition, the cerium-based metal organic framework may have soft physical properties and a porous structure in which the plurality of cerium hexanuclear nanoclusters are connected to the plurality of organic linkers to form the 3D network structure. Accordingly, during the CMP process using the slurry composition SC, even when the abrasive including the cerium-based metal organic framework is exposed to shear stress applied from the outside and some of the plurality of cerium hexanuclear nanoclusters fall off from the abrasive, the cerium-based metal organic framework having the 3D network structure may remain exposed at a surface of the abrasive. Therefore, even when a physical change occurs in the abrasive due to the shear stress applied to the abrasive during the CMP process, it is very unlikely that the physical change in the abrasive will adversely affect polishing performance or cause scratch defects in a film to be polished.

In addition, because the abrasive including the cerium-based metal organic framework, which is in the slurry composition SC according to embodiments, has the 3D network structure, the abrasive may flexibly respond to external pressure during the CMP process and serve as a cushion on a surface of the film to be polished during the CMP process, thereby reducing scratch defects on the surface of the film to be polished. Also, because the cerium hexanuclear nanocluster included in the cerium-based metal organic framework has substantially the same crystal structure as a ceria particle, the cerium hexanuclear nanocluster may form relatively strong chemical bonds to the film (e.g., a silicon oxide film) to be polished, which has Si—O bonds, during the CMP process. Accordingly, during the CMP process, the cerium hexanuclear nanocluster included in the cerium-based metal organic framework may interact with the film to be polished through the chemical bonds.

Furthermore, because the cerium-based metal organic framework included in the abrasive has the 3D network structure in which the plurality of cerium hexanuclear nanoclusters are connected to the plurality of organic linkers, the cerium-based metal organic framework may have a greater particle size than a typical abrasive. Accordingly, the cerium-based metal organic framework may overcome the physical limitations of a typical abrasive or an abrasive including only the cerium hexanuclear nanoclusters and relatively strongly interact with a film to be polished, and thus, a polishing rate may increase. Also, in a cleaning process performed after the polishing process is finished, removing the abrasive from a surface of the film to be polished may be easy.

As described above, when the film to be polished is polished by using the slurry composition SC according to embodiments, a polishing rate of the film to be polished may be increased while limiting and/or preventing the occurrence of defects (e.g., scratches) or physical damage on a polished surface of the film to be polished. Also, the efficiency of the polishing process may improve, and productivity in a process of manufacturing an IC device may be improved.

The abrasive including the cerium-based metal organic framework included in the slurry composition SC according to embodiments may be manufactured by using various synthesis processes that are known in the art.

In embodiments, to synthesize the cerium-based metal organic framework, after a cerium hexanuclear nanocluster is first synthesized, the cerium hexanuclear nanocluster may be reacted with an organic linker precursor. Thus, the cerium-based metal organic framework may be synthesized. In other embodiments, to synthesize the cerium-based metal organic framework, precursors required for the synthesis of the cerium hexanuclear nanocluster and an organic linker precursor may be mixed and reacted together. In this case, a 3D shape of the cerium-based metal organic framework, a method of connecting the cerium-based metal organic framework to an organic linker, and porosity of the cerium-based metal organic framework may vary according to a type of the organic linker precursor. Accordingly, the 3D shape of the cerium-based metal organic framework, the method of connecting the cerium-based metal organic framework to the organic linker, and the porosity of the cerium-based metal organic framework may be adjusted by appropriately selecting a type of the organic linker precursor as needed.

An example of a process of synthesizing the cerium-based metal organic framework by reacting a cerium hexanuclear nanocluster with an organic linker precursor after the cerium hexanuclear nanocluster is first synthesized is now described.

First, ammonium cerium (IV) nitrate is mixed with glycine to form the cerium hexanuclear nanocluster, a cerium hexanuclear nanocluster may be precipitated by using a NaCl solution, and the precipitated cerium hexanuclear nanocluster may be recovered. Here, a weight ratio of ammonium cerium (IV) nitrate to glycine may be in a range of about 10:2 to about 10:3. Thereafter, the cerium hexanuclear nanocluster powder, the organic linker precursor, and a modulator may be mixed with a solution of water and dimethylformamide (DMF), and the obtained mixture may be aged in an oven maintained at a temperature of 100° C., and thus, the cerium-based metal organic framework may be synthesized. Here, specific examples of the organic linker precursor are the same as those described above. For example, benzene-1,4-dicarboxylic acid may be used as the organic linker precursor. In this case, a weight ratio of the cerium hexanuclear nanocluster powder to benzene-1,4-dicarboxylic acid may be 13:11. Benzoic acid or acetic acid may be used as the modulator, without being limited thereto. The use of the modulator may be omitted.

In another method of synthesizing a cerium-based metal organic framework, ammonium cerium (IV) nitrate and benzene-1,4-dicarboxylic acid may be mixed at a molar ratio of 1:1, and the obtained mixture may be dispersed in a solution obtained by mixing water and DMF in a volume ratio of 4:1. A modulator, such as benzoic acid or acetic acid, may be added to the obtained solution. The resultant product may be aged in an oven maintained at a temperature of 100° C. to synthesize the cerium-based metal organic framework. Specific examples of the organic linker precursor are the same as those described above.

The cerium-based metal organic framework synthesized as described above may be purified and mixed with water, and an additive (e.g., a pH adjuster) may be mixed with the resultant mixture. Thus, a slurry composition according to inventive concepts may be manufactured.

Next, a method of manufacturing an IC device according to embodiments is described in detail.

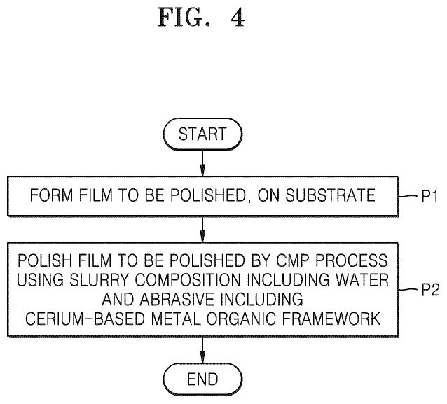

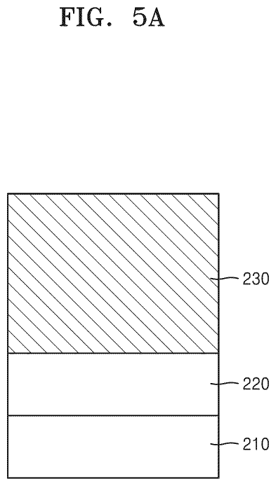

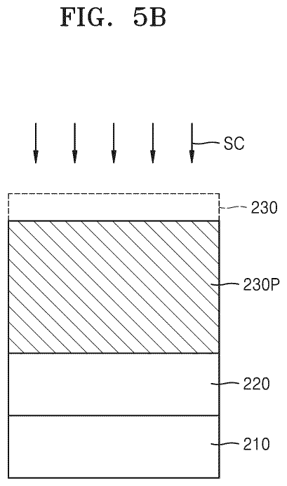

FIG. 4 is a flowchart of a method of manufacturing an IC device, according to embodiments. FIGS. 5A and 5B are cross-sectional views of a process sequence of a method of manufacturing an IC device, according to embodiments.

Referring to FIGS. 4 and 5A, in process P1, a lower structure 220 may be formed on a substrate 210, and an object to be polished, which includes a film 230 to be polished (or a to-be-polished film 230), may be formed on the lower structure 220.

The substrate 210 may include a semiconductor (e.g., silicon (Si) or germanium (Ge)) or a compound semiconductor (e.g., silicon germanium (SiGe), silicon carbide (SiC), gallium arsenide (GaAs), indium arsenide (InAs), or indium phosphide (InP)). The substrate 210 may include a conductive region (not shown). The conductive region may include a doped well, a doped structure, or a conductive layer.

The lower structure 220 may include an insulating film, which includes a silicon oxide film, a silicon nitride film, or a combination thereof. In some other embodiments, the lower structure 220 may include various conductive regions (e.g., wiring layers, contact plugs, and transistors) and insulating patterns configured to insulate the conductive regions from each other.

The to-be-polished film 230 may include an insulating film, a semiconductor film, a metal film, or an alloy film thereof. In embodiments, the to-be-polished film 230 may include a silicon-containing film (e.g., a silicon oxide film) having a Si—O bond.

Referring to FIGS. 4 and 5B, in process P2, the to-be-polished film 230 may be polished by a CMP process using a slurry composition SC according to embodiments of inventive concepts. As a result, a planarized film 230P having a smaller thickness than the metal-containing film 230 may be obtained. For brevity, a top surface of the to-be-polished film 230 shown in FIG. 5A is illustrated with a dashed line in FIG. 5B. A detailed composition of the slurry composition SC is the same as that described above.

The polishing process on the to-be-polished film 230, which is shown in process P2 of FIG. 4 and FIG. 5A, may be a process of buff polishing the to-be-polished film 230 by using the slurry composition SC to remove local steps on the top surface of the to-be-polished film 230 or remove seams in an upper portion of the to-be-polished film 230. The planarized film 230P, which is obtained by buff polishing the to-be-polished film 230, may have a smooth and flat top surface.

In embodiments, the slurry composition SC used in the polishing process on the to-be-polished film 230, which is shown in process P2 of FIG. 4 and FIG. 5A, may include an abrasive having a 3D network structure including the cerium-based metal organic framework 100 described with reference to FIG. 2, and water. The cerium-based metal organic framework 100 may include a plurality of cerium hexanuclear nanoclusters (refer to 110 in FIG. 3A), each of which includes six cerium atoms, and a plurality of organic linkers, each of which is connected between two selected ones of the plurality of cerium hexanuclear nanoclusters 110. Each of the plurality of organic linkers may have a plurality of anionic functional groups and be chemically bonded to at least two selected ones of the plurality of cerium hexanuclear nanoclusters 110 through the plurality of anionic functional groups. Each of the plurality of organic linkers may have two, three, or four carboxylate functional groups (—COO⁻). Specific examples of the plurality of organic linkers are the same as those described above. For example, each of the plurality of organic linkers included in the cerium-based metal organic framework may include an aromatic ring. In embodiments, each of the plurality of organic linkers may include the organic linker 120 shown in FIG. 3B.

In other embodiments, the slurry composition SC used in the process of polishing the to-be-polished film 230 shown in FIG. 5A according to the process P2 of FIG. 4 may include a cerium-based metal organic framework including the bonding structure represented by General formula 1 described above.

In still other embodiments, the abrasive included in the slurry composition SC used in the process of polishing the to-be-polished film 230 shown in FIG. 5A according to the process P2 of FIG. 4 may include a cerium-based metal organic framework, which includes a plurality of cerium hexanuclear nanoclusters, each of which includes six cerium atoms, and a plurality of organic linkers, each of which is connected between two selected ones of the plurality of cerium hexanuclear nanoclusters, and the cerium-based metal organic framework may have a 3D network structure. In embodiments, each of the plurality of cerium hexanuclear nanoclusters may include a bonding structure, which has a composition represented by Formula 1 or Formula 2 and is represented by General formula 1.

The slurry composition SC used in the process of polishing the to-be-polished film 230 shown in FIG. 5A according to process P2 of FIG. 4 may further include at least one additive selected from a dispersant, a pH adjuster, a corrosion inhibitor, and a polishing booster. Specific compositions and examples of the additive are the same as those described above.

According to the method of manufacturing the IC device, which has been described with reference to FIGS. 4, 5A, and 5B, the to-be-polished film 230 may be polished by using the slurry composition SC according to inventive concepts. Thus, defects (e.g., scratches) or physical damage may be limited and/or prevented from occurring on a polished surface of the to-be-polished film 230, and a polishing rate of the to-be-polished film 230 may increase. More specifically, the cerium-based metal organic framework included in the abrasive of the slurry composition SC may have a 3D network structure in which the plurality of cerium hexanuclear nanoclusters are connected to the plurality of organic linkers. Thus, the cerium-based metal organic framework may have a porous structure and soft physical properties. Thus, while the to-be-polished film 230 is being polished by a CMP process using the slurry composition SC, even when the abrasive including the cerium-based metal organic framework is exposed to shear stress applied from the outside, the cerium-based metal organic framework having the 3D network structure may remain exposed at a surface of the abrasive. Accordingly, even when physical changes occur in the abrasive due to shear stress applied to the abrasive during the CMP process, it is very unlikely that the physical changes in the abrasive will adversely affect polishing performance or cause scratch defects to a film to be polished. Because the abrasive including the cerium-based metal organic framework included in the slurry composition SC has the 3D network structure, the abrasive may flexibly respond to external pressure during the CMP process and serve as a cushion on a surface of the film to be polished during the CMP process, thereby reducing scratch defects on the surface of the film to be polished. Therefore, productivity in a process of manufacturing an IC device by performing the CMP process using the slurry composition SC may improve, and an IC device with improved reliability may be provided.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While inventive concepts have been particularly shown and described with reference to embodiments thereof, it will be understood that various changes in form and details may be made therein without departing from the spirit and scope of the following claims.

What is claimed is:

1. A polishing slurry composition, comprising
an abrasive; and
water, wherein
the abrasive includes a cerium-based metal organic framework,
the cerium-based metal organic framework has a three-dimensional (3D) network structure including a plurality of cerium hexanuclear nanoclusters,
each of the plurality of cerium hexanuclear nanoclusters includes six cerium atoms and a plurality of organic linkers, and
each of the plurality of organic linkers are connected between two corresponding cerium hexanuclear nanoclusters among the plurality of cerium hexanuclear nanoclusters.

2. The polishing slurry composition of claim 1, wherein, each of the plurality of cerium hexanuclear nanoclusters has a composition represented by Formula 1:
[Ce₆Oₓ(OH)₈₋ₓ(NH₃CH₂COO)₈]A_{y} [Formula 1]
wherein, in Formula 1,
x is an integer of 4 to 8,
y is an integer of 1 to 8, and
A comprises at least one of carboxylate, nitrate, amino acid salt, and a chlorine (C1) ion.

3. The polishing slurry composition of claim 1, wherein,
in the cerium-based metal organic framework, each of the plurality of organic linkers has a plurality of anionic functional groups and is chemically bonded to at least two cerium hexanuclear nanoclusters among the plurality of cerium hexanuclear nanoclusters through the plurality of anionic functional groups.

4. The polishing slurry composition of claim 1, wherein,
in the cerium-based metal organic framework, each of the plurality of organic linkers comprises substituted or unsubstituted C1 to C20 alkyl, substituted or unsubstituted C2 to C20 alkenyl, substituted or unsubstituted C2 to C20 alkynyl, substituted or unsubstituted C1 to C20 heteroalkyl, substituted or unsubstituted C2 to C20 heteroalkenyl, substituted or unsubstituted C2 to C20 heteroalkynyl, substituted or unsubstituted C3 to C20 cycloalkyl, substituted or unsubstituted C3 to C20 cycloalkenyl, or a substituted or unsubstituted C6 to C30 aromatic ring system.

5. The polishing slurry composition of claim 1, wherein, in the cerium-based metal organic framework, each of the plurality of organic linkers comprises a carboxylate obtained from at least one of benzene-1,4-dicarboxylic acid, 5-bromoisophthalic acid, 2-hydroxyterephthalic acid, 2,5-dihydroxyterephthalic acid, 5-cyano-1,3-benzenedicarboxylic acid, 2,5-diaminoterephthalic acid, 5-ethynyl-1,3-benzenedicarboxylic acid, 4,4′-biphenyldicarboxilic acid, 2,6-naphthalenedicarboxylic acid, 9,10-anthracenedicarboxylic acid, 2,2-diamino-4,4′-stilbenedicarboxylic acid, 2,2-dinitro-4,4-stilbenedicarboxylic acid, 1,3,5-tricarboxybenzene, biphenyl-3,4′,5-tricarboxylic acid, 1,3,5-tris(4-carboxyphenyl)benzene, 2,4,6-Tris(4-carboxyphenyl)-1,3,5-triazine, 1,3,5-tris(4-carboxy[1,1′-biphenyl]-4-yl)benzene, biphenyl-3,3,5,5′-tetracarboxylic acid, 1,2,4,5-tetrakis(4-carboxyphenyl)benzene, 1,4,7,10-tetraazacyclododecane-N,N′,N″,N′″-tetraacetic acid, and 1,1,2,2-tetra(4-carboxylphenyl)ethylene.

6. The polishing slurry composition of claim 1, further comprising:
a dispersant.

7. The polishing slurry composition of claim 1, further comprising:
a pH adjuster.

8. The polishing slurry composition of claim 1, further comprising:
at least one of a corrosion inhibitor and a polishing booster.

9. The polishing slurry composition of claim 1, wherein a content of the abrasive is in a range of 0.1 wt % to 2 wt %, based on a total weight of the polishing slurry composition.

10. A polishing slurry composition comprising:
an abrasive; and
water, wherein
the abrasive including a cerium-based metal organic framework having a three-dimensional (3D) network structure,
the cerium-based metal organic framework includes a bonding structure represented by General formula 1,
{[Ce₆]-L}ₙ [General formula 1]
wherein, in General formula 1, [Ce₆] is a cerium hexanuclear nanocluster including six cerium atoms and a plurality of oxygen atoms, L is an organic linker, and n is an integer of 2 or more.

11. The polishing slurry composition of claim 10, wherein,
in the cerium-based metal organic framework, each of the plurality of organic linkers comprises substituted or unsubstituted C1 to C20 alkyl, substituted or unsubstituted C2 to C20 alkenyl, substituted or unsubstituted C2 to C20 alkynyl, substituted or unsubstituted C1 to C20 heteroalkyl, substituted or unsubstituted C2 to C20 heteroalkenyl, substituted or unsubstituted C2 to C20 heteroalkynyl, substituted or unsubstituted C3 to C20 cycloalkyl, substituted or unsubstituted C3 to C20 cycloalkenyl, or a substituted or unsubstituted C6 to C30 aromatic ring system.

12. The polishing slurry composition of claim 10, wherein, in the cerium-based metal organic framework, the organic linker comprises an aromatic ring.

13. The polishing slurry composition of claim 10, further comprising:
at least one of a dispersant, a pH adjuster, a corrosion inhibitor, and a polishing booster.

14. A method of manufacturing an integrated circuit device, the method comprising:
forming a film to be polished on a substrate; and
polishing the film to be polished by performing a chemical mechanical polishing (CMP) process using a slurry composition,
the slurry composition including an abrasive and water, the abrasive comprising a cerium-based metal organic framework, wherein
the cerium-based metal organic framework has a three-dimensional (3D) network structure including a plurality of cerium hexanuclear nanoclusters,
each of the plurality of cerium hexanuclear nanoclusters includes six cerium atoms and a plurality of organic linkers, and
each of the plurality of organic linkers are connected between two corresponding cerium hexanuclear nanoclusters among the plurality of cerium hexanuclear nanoclusters.

15. The method of claim 14, wherein the cerium-based metal organic framework comprises a bonding structure represented by General formula 1:
{[Ce₆]-L}ₙ [General formula 1]
wherein, in General formula 1, [Ce₆] is a cerium hexanuclear nanocluster comprising six cerium atoms and a plurality of oxygen atoms, L is an organic linker, and n is an integer of 2 or more.

16. The method of claim 14, wherein, in the cerium-based metal organic framework, each of the plurality of organic linkers has a plurality of anionic functional groups and is chemically bonded to at least two cerium hexanuclear nanocluster among the plurality of cerium hexanuclear nanoclusters through the plurality of anionic functional groups.

17. The method of claim 14, wherein, in the cerium-based metal organic framework, each of the plurality of organic linkers comprises substituted or unsubstituted C1 to C20 alkyl, substituted or unsubstituted C2 to C20 alkenyl, substituted or unsubstituted C2 to C20 alkynyl, substituted or unsubstituted C1 to C20 heteroalkyl, substituted or unsubstituted C2 to C20 heteroalkenyl, substituted or unsubstituted C2 to C20 heteroalkynyl, substituted or unsubstituted C3 to C20 cycloalkyl, substituted or unsubstituted C3 to C20 cycloalkenyl, or a substituted or unsubstituted C6 to C30 aromatic ring system.

18. The method of claim 14, wherein, in the cerium-based metal organic framework, each of the plurality of organic linkers comprises a carboxylate obtained from at least one of benzene-1,4-dicarboxylic acid, 5-bromoisophthalic acid, 2-hydroxyterephthalic acid, 2,5-dihydroxyterephthalic acid, 5-cyano-1,3-benzenedicarboxylic acid, 2,5-diaminoterephthalic acid, 5-ethynyl-1,3-benzenedicarboxylic acid, 4,4′-biphenyldicarboxilic acid, 2,6-naphthalenedicarboxylic acid, 9,10-anthracenedicarboxylic acid, 2,2-diamino-4,4′-stilbenedicarboxylic acid, 2,2-dinitro-4,4-stilbenedicarboxylic acid, 1,3,5-tricarboxybenzene, biphenyl-3,4′,5-tricarboxylic acid, 1,3,5-Tris(4-carboxyphenyl)benzene, 2,4,6-Tris(4-carboxyphenyl)-1,3,5-triazine, 1,3,5-tris(4-carboxy[1,1′-biphenyl]-4-yl)benzene, biphenyl-3,3,5,5′-tetracarboxylic acid, 1,2,4,5-tetrakis(4-carboxyphenyl)benzene, 1,4,7,10-tetraazacyclododecane-N,N′,N″,N′″-tetraacetic acid, and 1,1,2,2-tetra(4-carboxylphenyl)ethylene.

19. The method of claim 14, wherein the slurry composition further comprises at least one of a dispersant, a pH adjuster, and a corrosion inhibitor, and a polishing booster.

20. The method of claim 14, wherein the film to be polished comprises a silicon-containing film.
